(19) United States
(12) Patent Application Publication
(10) Pub. No.: US 2024/0177768 A1
(43) Pub. Date: May 30, 2024

(54) APPARATUS AND METHOD WITH IN-MEMORY COMPUTING (IMC) PROCESSOR

(71) Applicant: SAMSUNG ELECTRONICS CO., LTD., Suwon-si (KR)

(72) Inventors: Seungchul JUNG, Suwon-si (KR); Seok Ju YUN, Suwon-si (KR); Soon-Wan KWON, Suwon-si (KR)

(73) Assignee: SAMSUNG ELECTRONICS CO., LTD., Suwon-si (KR)

(21) Appl. No.: 18/350,416

(22) Filed: Jul. 11, 2023

(30) Foreign Application Priority Data
Nov. 28, 2022 (KR) 10-2022-0161777

(51) Int. Cl. G11C 11/412; H03K 19/20; H03K 19/21

(52) U.S. Cl. CPC G11C 11/412; H03K 19/20; H03K 19/215

(57) ABSTRACT

An apparatus includes a static random access memory (SRAM) cell including a first inverter and a second inverter, and a third inverter including a first inverter transistor and a second inverter transistor. An output terminal of the first inverter is connected to a source terminal of the second inverter transistor.

### CROSS-REFERENCE TO RELATED APPLICATIONS

This application claims the benefit under 35 USC § 119(a) of Korean Patent Application No. 10-2022-0161777, filed on Nov. 28, 2022, in the Korean Intellectual Property Office, the entire disclosure of which is incorporated herein by reference for all purposes.

### BACKGROUND

### 1. Field

The following description relates to an apparatus and method with in-memory computing (IMC) processor.

### 2. Description of Related Art

Typically, deep neural networks (DNNs) are machine learning algorithms based on artificial intelligence (AI). A convolutional neural network (CNN), one type of DNN, is widely used in various application fields such as image and signal processing, object recognition, computer vision, and the like. Inferencing and training of a CNN typically involves performing a multiply and accumulate (MAC) operation that repeats multiplication and addition using a considerably large number of matrices. When a CNN application is executed using general-purpose processors, an operation, for example, a MAC operation that calculates an inner product of two vectors and accumulates and sums the values, is typically performed through in-memory computing.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, an apparatus includes a static random access memory (SRAM) cell including a first inverter and a second inverter, and a third inverter including a first inverter transistor and a second inverter transistor. An output terminal of the first inverter may be connected to a source terminal of the second inverter transistor.

The apparatus may be configured to perform an operation between input data input through an input terminal of the third inverter and output data of the second inverter and output a result of the operation through an output terminal of the third inverter.

The result of the operation may include a NOR operation result between the input data and the output data of the second inverter.

The apparatus may further include a pull-down transistor, and a gate terminal of the pull-down transistor may be connected to an output terminal of the second inverter.

The pull-down transistor may be an NMOS transistor, and an output terminal of the third inverter may be connected to a drain terminal of the pull-down transistor.

The apparatus may be configured to perform an operation between inverse input data input through an input terminal of the third inverter and output data of the first inverter and output a result of the operation through an output terminal of the third inverter.

The result of the operation may include an AND operation result between input data corresponding to the inverse input data and the output data of the first inverter.

In one or more general aspects, an apparatus includes an SRAM cell including a first inverter and a second inverter, and an third inverter including a first inverter transistor and a second inverter transistor. An output terminal of the first inverter may be connected to a source terminal of the first inverter transistor.

The apparatus may be configured to perform an operation between input data input through an input terminal of the third inverter and output data of the first inverter and output a result of the operation through an output terminal of the third inverter.

The result of the operation may include a NAND operation result between the input data and the output data of the first inverter.

The apparatus may include a pull-up transistor, and a gate terminal of the pull-down transistor may be connected to an output terminal of the first inverter.

The pull-up transistor may be a PMOS transistor, and an output terminal of the third inverter may be connected to a drain terminal of the pull-up transistor.

The apparatus may be configured to perform an operation between inverse input data input through an input terminal of the third inverter and output data of the first inverter and output a result of the operation through an output terminal of the third inverter.

The result of the operation may include an OR operation result between input data corresponding to the inverse input data and the output data of the first inverter.

In another general aspect, an apparatus includes an SRAM cell including a first inverter and a second inverter, and a third inverter including a first inverter transistor and a second inverter transistor. An output terminal of the second inverter may be connected to a source terminal of the first inverter transistor, and an output terminal of the first inverter may be connected to a source terminal of the second inverter transistor.

The apparatus may be configured to perform an operation between input data input through an input terminal of the third inverter and output data of the second inverter and output a result of the operation through an output terminal of the third inverter.

In another general aspect, a processor-implemented method includes performing a first operation between input data input through an input terminal of a third inverter and output data of a second inverter and output a result of the operation through an output terminal of the third inverter; and perform a second operation between inverse input data input through an input terminal of the third inverter and output data of a first inverter and output a result of the operation through an output terminal of the third inverter.

The result of the first operation may include an NOR operation result between the input data and the output data of the second inverter.

The result of the second operation may include an AND operation result between input data corresponding to the inverse input data and the output data of the first inverter.

Other features and aspects will be apparent from the following detailed description, the drawings, and the claims.

### BRIEF DESCRIPTION OF THE DRAWINGS

FIG. 1 illustrates an example relationship between an in-memory computing (IMC) macro and an operation performed in a neural network according to one or more embodiments.

FIG. 2A illustrates an example data flow when a convolution operation is performed by an IMC processor according to one or more embodiments.

FIG. 2B illustrates an example structure of a static random access memory (SRAM) cell according to one or more embodiments.

FIGS. 3A through 3D illustrate an example IMC cell for performing a NOR operation according to one or more embodiments.

FIGS. 4A through 4C illustrate an example IMC cell for performing a NOR operation according to one or more embodiments.

FIGS. 5A through 5D illustrate an example IMC cell for performing a NAND operation according to one or more embodiments.

FIGS. 6A through 6C illustrate an example IMC cell for performing a NAND operation according to one or more embodiments.

FIGS. 7A through 7C illustrate an example IMC cell for performing an XOR operation according to one or more embodiments.

FIGS. 8A and 8B illustrate an example IMC cell for performing an AND operation according to one or more embodiments.

FIGS. 9A and 9B illustrate an example IMC cell for performing an OR operation according to one or more embodiments.

Throughout the drawings and the detailed description, unless otherwise described or provided, the same or like drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

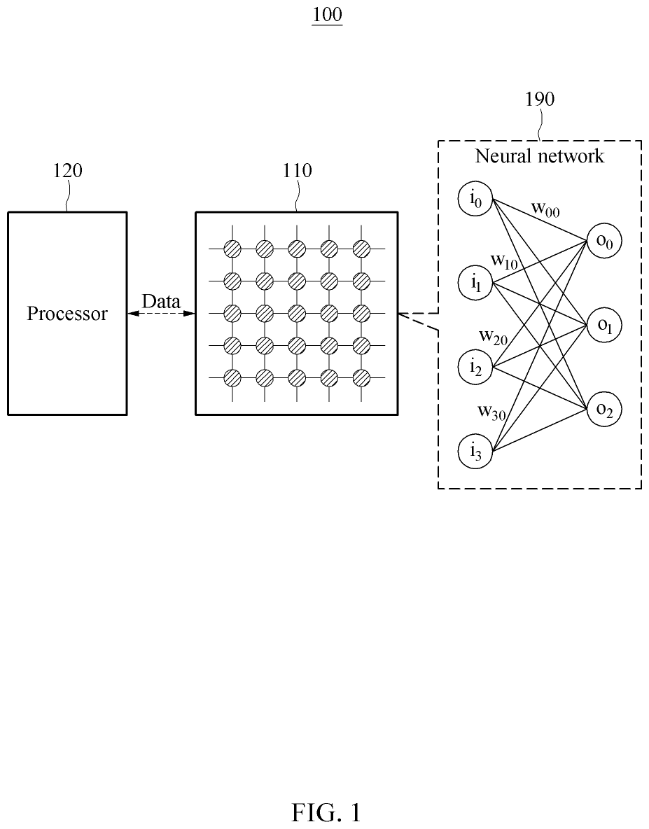

FIG. 1 illustrates an example in-memory computing (IMC) system 100 for a multiply and accumulate (MAC) operation in a neural network according to one or more embodiments.

In Von Neumann architecture, limitations on performance and power occur due to frequent data movement between an operator (processor) and memory. The IMC system 100 may allow operations to be performed directly in a memory device 110, and thus reduce data movement between, as shown in FIG. 1 for example, a processor 120 and the memory device 110, thereby increasing power efficiency. In the IMC system 100, the processor 120 may be configured to input data to be operated to the memory device 110, and the memory device 110 may be configured to perform an operation by itself on the inputted data. The processor 120 may read a result of the operation from the memory device 110, thereby minimizing the data transmission during an operation process.

In one example, the IMC system 100 may be configured to perform the MAC operation frequently used in an artificial intelligence (AI) algorithm among various operations. As shown in FIG. 1, a layer operation 190 in a neural network may include the MAC operation of adding results (O₀, O₁ and O₂) obtained by multiplying weights (W₀₀, W₁₀, W₂₀ and W₃₀) by each of input values of input nodes (i₀, i₁, i₂ and i₃). An example MAC operation may be expressed as in Equation 1 below.

$${O}_{0} = {\sum }_{m = 0}^{M - 1} {I}_{m} {W}_{0 , m} , {O}_{1} = {\sum }_{m = 0}^{M - 1} {I}_{m} {W}_{1 , m} , … , {O}_{T - 1} = {\sum }_{m = 0}^{M - 1} {I}_{m} {W}_{T - 1 , m} \qquad Equation 1$$

In Equation 1, for a current network layer, there are M inputs provided to each of T nodes of the current layer. Here, Oₜ represents an output of a t-th of the T nodes, Iₘ represents an m-th of the M inputs, and W_{t,m} represents a weight applied to an m-th input which is input to the t-th node. Also, Oₜ is an output of a node or a node value and may be calculated as a weighted sum of inputs Iₘ and weights W_{t,m}, m is an integer of 0 or more and M−1 or less, t is an integer of 0 or more and T−1 or less, and M and T are integers. Moreover, M is the number of nodes of a previous layer connected to one node of the current layer to be operated, and T is the number of nodes of the current layer.

The memory device 110 of the IMC system 100 may perform the MAC operation described above but is not limited to be used for the MAC operation. For example, the IMC system 100 may be used for any application involving matrix operations. The memory device 110 may also be referred to as a memory array or an IMC device.

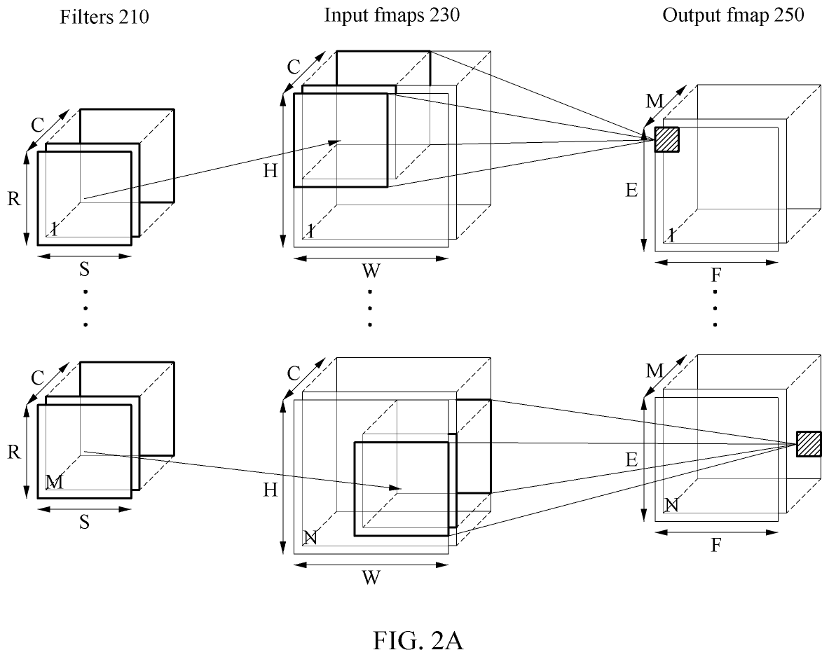

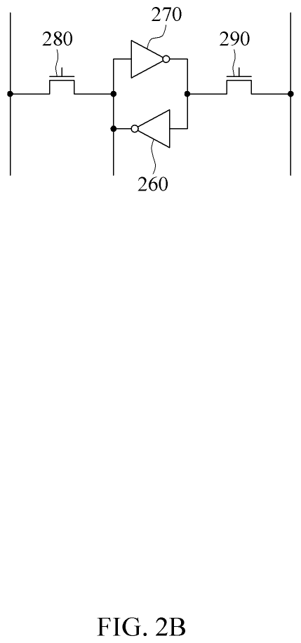

FIG. 2A illustrates an example data flow when a convolution operation is performed by an IMC processor according to one or more embodiments.

Referring to FIG. 2A, the data flow may include filters 210, input feature maps (IFMs) 230, and output feature maps (OFMs) 250 when a convolution operation is performed. The term “filter” may also be referred to as a “weight map”. Hereinafter, the terms “filter” and “weight map” may be used interchangeably.

In one example, as shown in FIG. 2A, regarding the filter 210, R and S denote a height and a weight of each of two-dimensional (2D) filters 210, respectively, C denotes the number of channels of each filter 210, and M denotes the number of three-dimensional (3D) filters 210. Regarding the IFMs 230, C denotes the number of input channels of each 2D IFM230, H and W denote a height and a width of each 2D IFM 230, respectively, and N denotes the number of the IFMs 230. Regarding the OFMs 250, E and F denote a height and a weight of each 2D OFM 250, respectively, M denotes the number of output channels of each 2D OFM 250, and N denotes the number of the OFMs 250.

A convolutional neural network (CNN) may include several convolutional layers. Each of the convolutional layers may generate a continuous, high-level abstracted value including unique information of input data. In one example, the abstracted value may be referred to as the above-described IFM 230.

When there are multiple feature maps or filters, each of the feature maps or filters may be called a “channel”. In FIG. 2A, the number of channels of each filter 210 (represented by C) is the same as the number of input channels of each IFM 230 (also represented by C). The number of output channels of each OFM 250 is represented by M. The N OFMs 250 may be generated by a convolution operation between the M filters 210 and the N IFMs 230.

The convolution operation may be performed by shifting the filters 210 of a predetermined size R×S by a pixel or stride of the IFM 230. Since the filters 210 and the IFMs 230 should have one-to-one correspondence according to the definition of convolution, the number of the channels of the filter 210 and the number of input channels of the IFM 230 are the same C. The number of filters 210 and the number of output channels of the OFM 250 are the same M. Here, the number of filters 210 and the number of channels of the OFMs 250 are the same, because output feature maps as many as the number of input feature maps may be generated per one channel when a convolution operation between the IFMs 230 and any one filter 210 is performed.

FIG. 2B illustrates an example structure of a static random access memory (SRAM) cell according to one or more embodiments.

Referring to FIG. 2B, an SRAM cell may include two inverters and two transistors. The two inverters included in the SRAM cell may be referred to as a first inverter 260 and a second inverter 270, respectively. The two transistors included in the SRAM cell may be referred to as a first pass transistor 280 and a second pass transistor 290, respectively.

As will be described in detail below, the first inverter 260 and the second inverter 270 may be CMOS inverters and each of them may include one PMOS transistor and one NMOS transistor. Both the first pass transistor 280 and the second pass transistor 290 may be NMOS transistors.

In order to write data to an SRAM cell, the SRAM cell may be selected by inputting first data (e.g., “1”) to a word line of the SRAM cell, and the first data 1 and second data (e.g., “0”) are respectively input to a bit line and a ˜ bit line (an opposite signal of the bit line). The second inverter 270 may receive the first data 1 as an input and output the second data 0. The first inverter 260 may receive the second data 0 as an input and output the first data 1. In this state, when the input of the word line is set as the second data 0, the first pass transistor 280 and the second pass transistor 290 are turned off, and no new data may be input or output. As a result, the data is thus written and maintained in the SRAM cell.

To perform a read operation, an SRAM cell may be selected by inputting the first data 1 to a word line, and the first pass transistor 280 and the second pass transistor 290 are turned on. Thus, the first data 1, which is the output of the first inverter 260, may be output to the bit line, and the second data 0, which is the output of the second inverter 270, may be output to the ˜ bit line. As a result, the data is thus read from the SRAM cell. Hereinafter, the output of the first inverter 260 may be referred to as first internal data, and the output of the second inverter 270 may be referred to as second internal data.

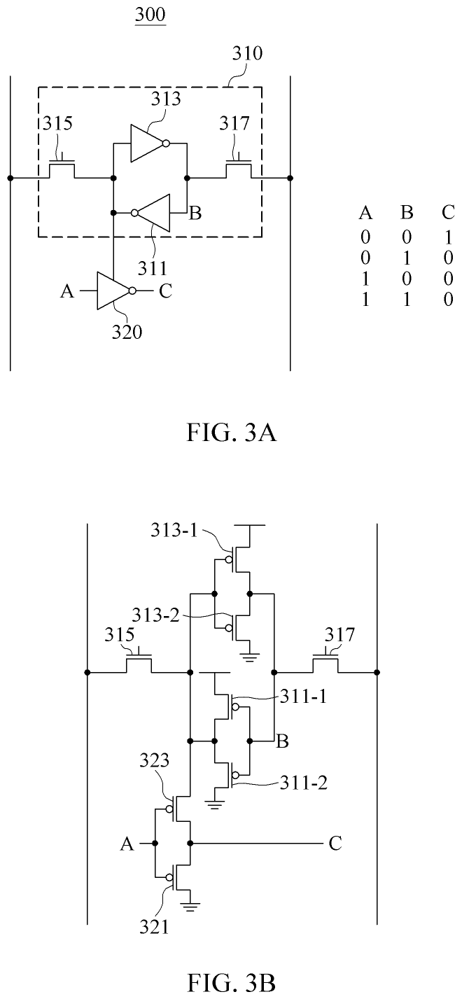

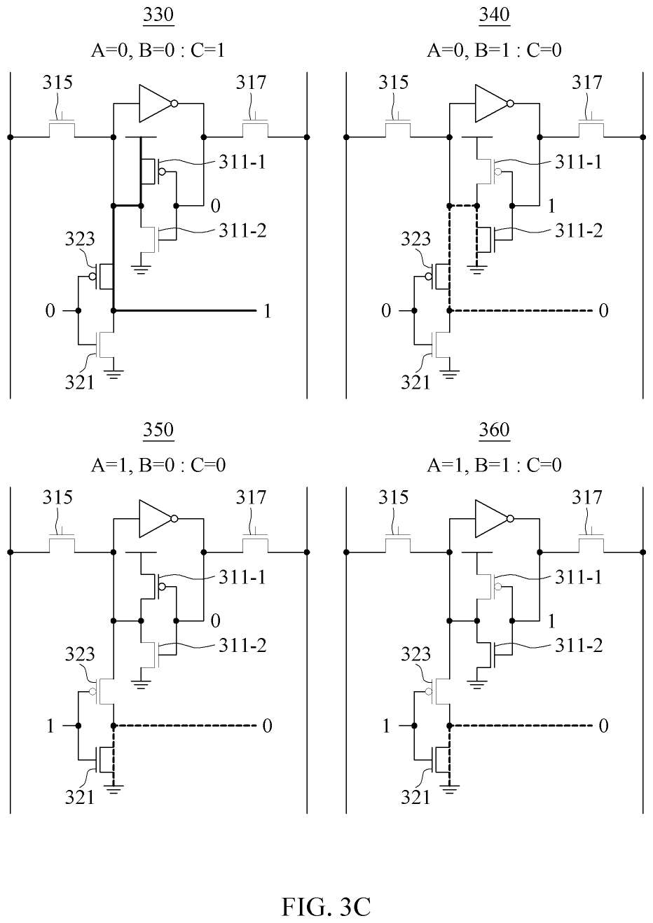

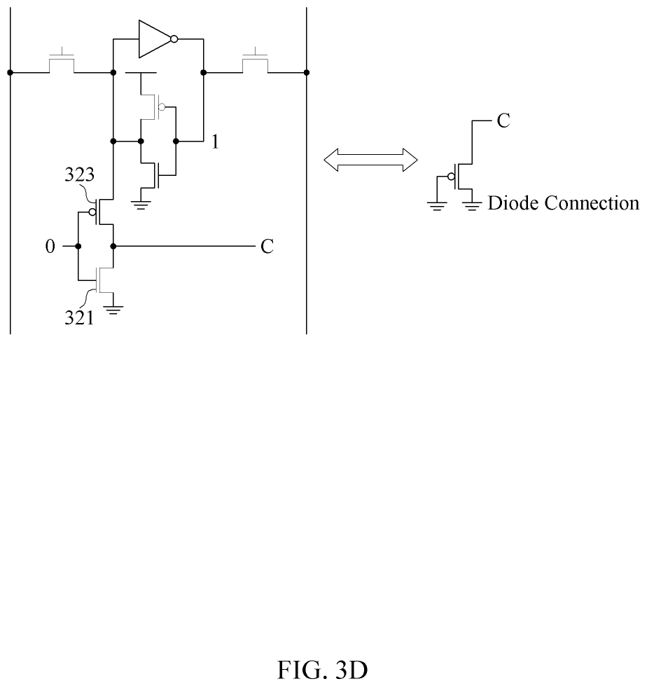

FIGS. 3A through 3D illustrate an example IMC cell for performing a NOR operation according to one or more embodiments.

Referring to FIG. 3A, an IMC cell 300 may include an SRAM cell 310 and a third inverter 320. The SRAM cell 310 may include a first inverter 311, a second inverter 313, a first pass transistor 315, and a second pass transistor 317. An output of the first inverter 311 may be used as a supply voltage of the third inverter 320.

The IMC cell 300 may perform an operation between input data A input through an input terminal of the third inverter 320 and second internal data B of the SRAM cell 310 and output a NOR operation result C through an output terminal of the third inverter 320. Here, the second internal data B may be output data of the second inverter 313.

Each of the first inverter 311, the second inverter 313, and the third inverter 320 may include one PMOS transistor and one NMOS transistor. Thus, the IMC cell 300 may be implemented as shown in FIG. 3B.

Referring to FIG. 3B, the first inverter 311 may include a first SRAM PMOS transistor 311-1 and a first SRAM NMOS transistor 311-2, the second inverter 313 may include a second SRAM PMOS transistor 313-1 and a second SRAM NMOS transistor 313-2, and the third inverter 320 may include a first inverter transistor 321 and a second inverter transistor 323. The first inverter transistor 321 may be an NMOS transistor, and the second inverter transistor 323 may be a PMOS transistor.

An output terminal (or a drain terminal) of the first inverter 311 may be connected to a source terminal of the second inverter transistor 323. A gate terminal of the third inverter 320 may function as an input terminal of the third inverter 320, and a drain terminal of the third inverter 320 may function as an output terminal of the third inverter 320.

For convenience of description below, the input data is referred to as A, the second internal data of the SRAM cell 310 is referred to as B, an operation result between A and B is referred to as C, the first data is 1, and the second data is 0.

FIG. 3C illustrates example operations of the IMC 300 in four cases that correspond to the rows of the truth table shown in FIG. 3A. Referring to a first case 330, when A is 0 and B is 0, the first SRAM PMOS transistor 311-1 is turned on, the first SRAM NMOS transistor 311-2 is turned off, the first inverter transistor 321 is turned off, and the second inverter transistor 323 is turned on. Therefore, power is supplied to the third inverter 320, and as a result, C is 1.

Referring to a second case 340, when A is 0 and B is 1, the first SRAM PMOS transistor 311-1 is turned off, the first SRAM NMOS transistor 311-2 is turned on, the first inverter transistor 321 is turned off, and the second inverter transistor 323 is turned on. Therefore, power is not supplied to the third inverter 320, and as a result, C is 0.

Referring to a third case 350, when A is 1 and B is 0, the first SRAM PMOS transistor 311-1 is turned on, the first SRAM NMOS transistor 311-2 is turned off, the first inverter transistor 321 is turned on, and the second inverter transistor 323 is turned off. Therefore, the output of the third inverter 320 is connected to a ground by the first inverter transistor 321, and as a result C is 0.

Referring to a fourth case 360, when A is 1 and B is 1, the first SRAM PMOS transistor 311-1 is turned off, the first SRAM NMOS transistor 311-2 is turned on, the first inverter transistor 321 is turned on, and the second inverter transistor 323 is turned off. Therefore, the output of the third inverter 320 is connected to the ground by the first inverter transistor 321, and as a result, C is 0.

As described in the first through the fourth cases 330-360, the IMC cell 300 may output a NOR operation result C between the input data A and the second internal data B of the SRAM cell 310 by using eight transistors.

However, referring to FIG. 3D, the second case 340 may correspond to a diode connection in which C is connected to the ground through the second inverter transistor 323 of the third inverter 320, and thus, a problem occurs in that the output may not flow down to the ground smoothly, because only the first case 330 has an output of 1. Considering a case of changing from the first case 330 to the second case 340, A should remain 0 and B should change from 0 to 1. However, as described above, B may be a weight of the internal data in the SRAM cell 310 which is a value that does not change. Therefore, according to the second case 340, the output may not flow down to the ground smoothly due to the diode connection, but if the weight is stored in the SRAM cell 310, the above problem can be prevented.

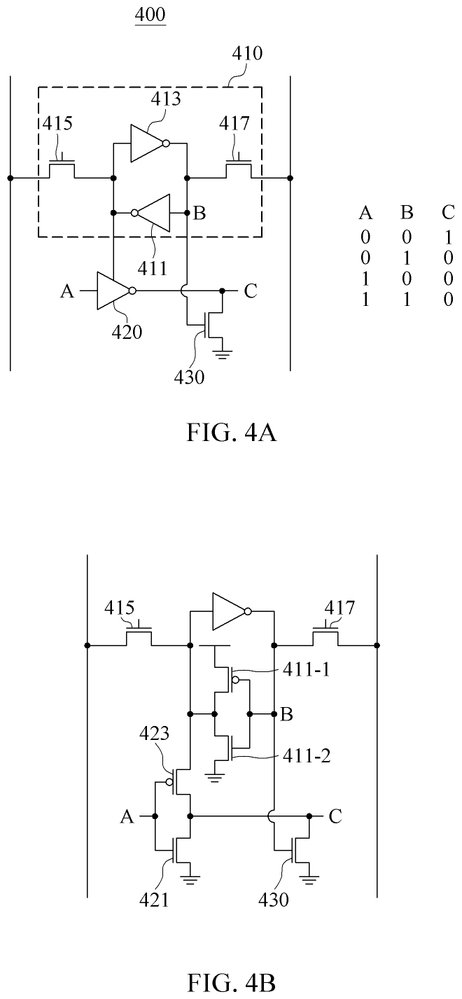

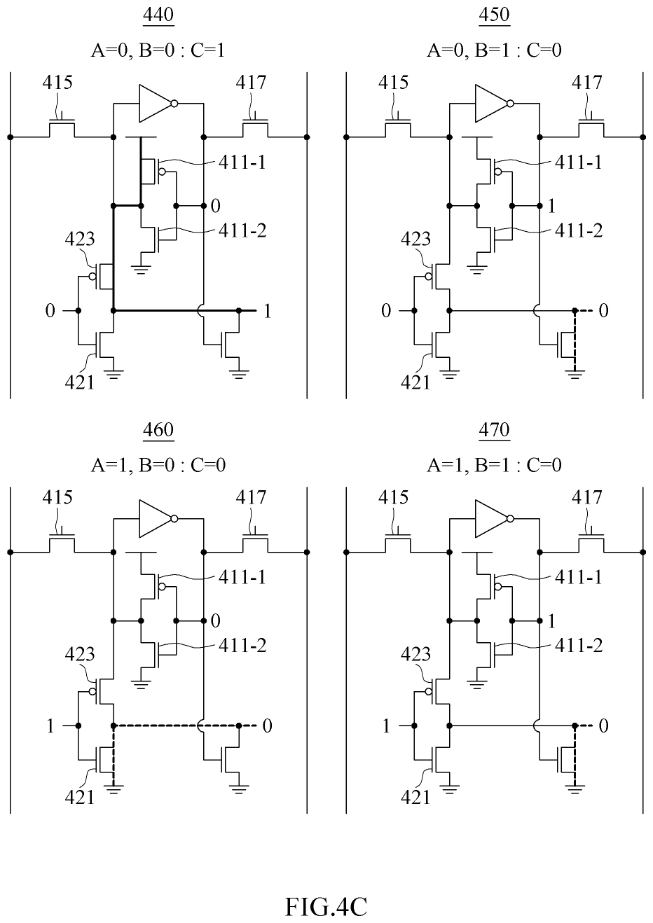

FIGS. 4A through 4C illustrate an example IMC cell for performing a NOR operation according to one or more embodiments.

Referring to FIG. 4A, an IMC cell 400 may include an SRAM cell 410, a third inverter 420, and a pull-down transistor 430. The SRAM cell 410 may include a first inverter 411, a second inverter 413, a first pass transistor 415, and a second pass transistor 417. An output of the first inverter 411 may be used as a supply voltage of the third inverter 420.

The IMC cell 400 may perform a NOR operation between input data A (input through an input terminal of the third inverter 420) and second internal data B of the SRAM cell 410 and output the NOR operation result C through an output terminal of the third inverter 420. Here, the second internal data B may be output data of the second inverter 413 as described above.

Each of the first inverter 411, the second inverter 413, and the third inverter 420 may include one PMOS transistor and one NMOS transistor, and thus, the IMC cell 400 may be implemented as shown in FIG. 4B.

Referring to FIG. 4B, the first inverter 411 may include a first SRAM PMOS transistor 411-1 and a first SRAM NMOS transistor 411-2, and the third inverter 420 may include a first inverter transistor 421 and a second inverter transistor 423. The first inverter transistor 421 may be an NMOS transistor, and the second inverter transistor 423 may be a PMOS transistor.

An output terminal (or a drain terminal) of the first inverter 411 may be connected to a source terminal of the second inverter transistor 423. A gate terminal of the pull-down transistor 430 may be connected to an output terminal of the second inverter 413 (or an input terminal of the first inverter 411). A gate terminal of the third inverter 420 may be an input terminal of the third inverter 420, and a drain terminal of the third inverter 420 may be an output terminal of the third inverter 420.

The IMC cell 400 may be configured to prevent occurrence of a diode connection by using the pull-down transistor 430. FIG. 4C illustrates example operations of the IMC 400 for the four truth table rows shown in FIG. 4A. In a first case 440, when A is 0 and B is 0, the first SRAM PMOS transistor 411-1 is turned on, the first SRAM NMOS transistor 411-2 is turned off, the first inverter transistor 421 is turned off, the second inverter transistor 423 is turned on, and the pull-down transistor 430 is turned off. Therefore, power is supplied to the third inverter 420, and as a result, C is 1.

In a second case 450, when A is 0 and B is 1, the first SRAM PMOS transistor 411-1 is turned off, the first SRAM NMOS transistor 411-2 is turned on, the first inverter transistor 421 is turned off, the second inverter transistor 423 is turned on, and the pull-down transistor 430 is turned on. The pull-down transistor 430 is connected to the ground, and as a result, C is 0.

In a third case 460, when A is 1 and B is 0, the first SRAM PMOS transistor 411-1 is turned on, the first SRAM NMOS transistor 411-2 is turned off, the first inverter transistor 421 is turned on, the second inverter transistor 423 is turned off, and the pull-down transistor 430 is turned on. Therefore, the output of the inverter 420 is connected to the ground by the first inverter transistor 421, and as a result, C is 0.

In a fourth case 470, when A is 1 and B is 1, the first SRAM PMOS transistor 411-1 is turned off, the first SRAM NMOS transistor 411-2 is turned on, the first inverter transistor 421 is turned on, the second inverter transistor 423 is turned off, and the pull-down transistor 430 is turned on. The pull-down transistor 430 is connected to the ground, and as a result, C is 0.

As described in the first through the fourth cases 440-470, the IMC cell 400 may output an NOR operation result C between the input data A and the second internal data B of the SRAM cell 410 by using nine transistors.

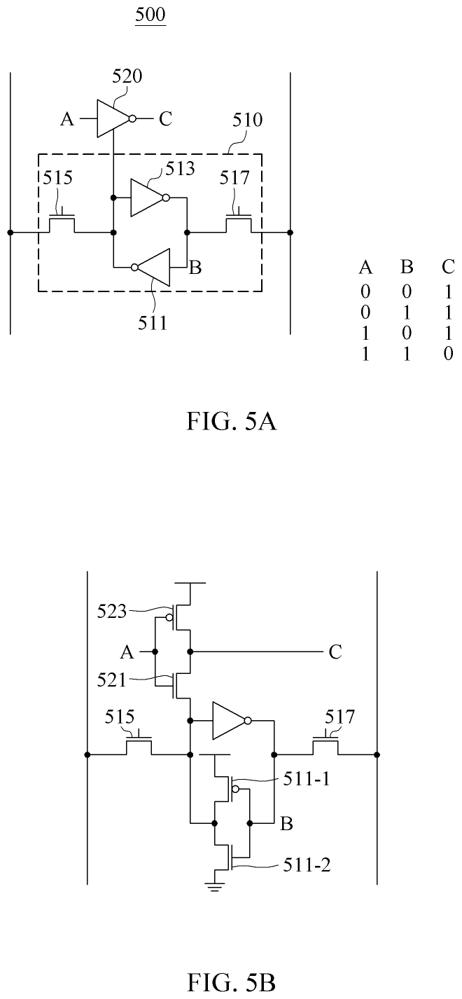

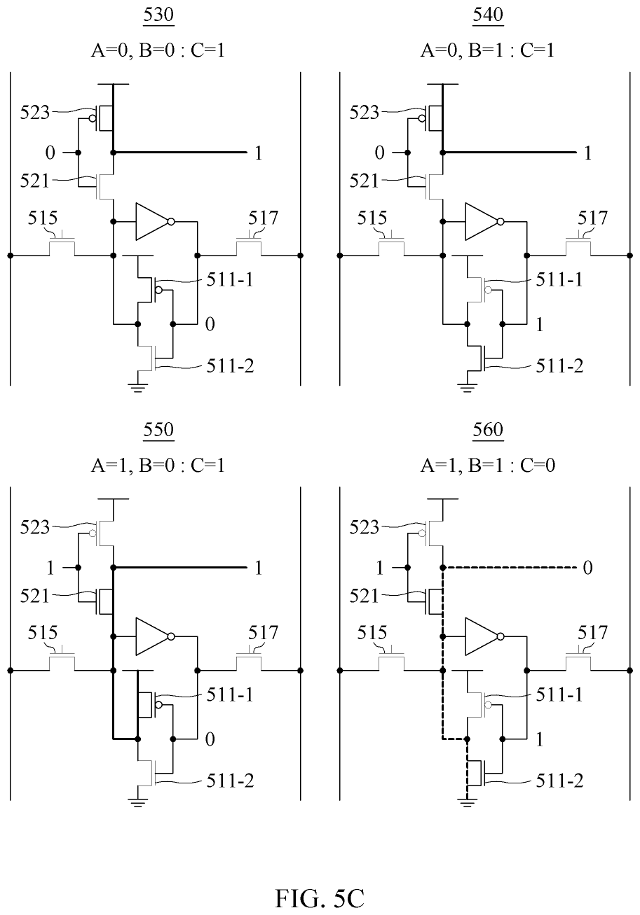

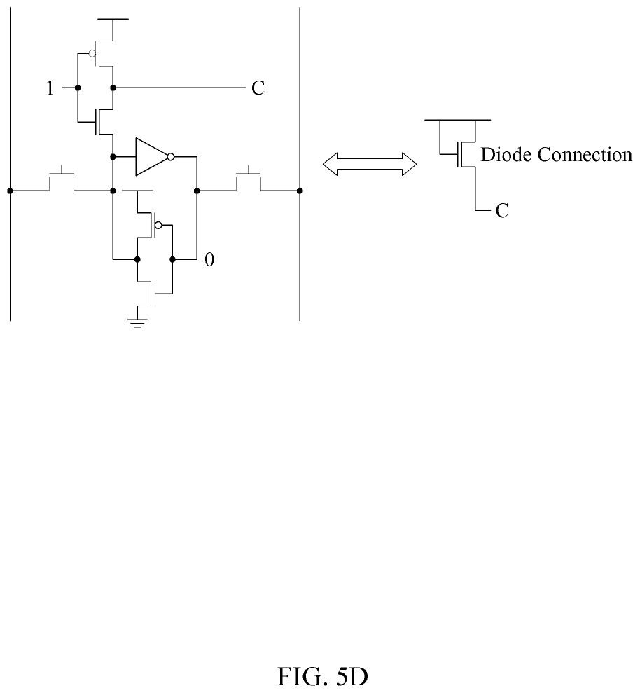

FIGS. 5A to 5D illustrate an example IMC cell for performing a NAND operation.

Referring to FIG. 5A, an IMC cell 500 may include an SRAM cell 510 and a third inverter 520. The SRAM cell 510 may include a first inverter 511, a second inverter 513, a first pass transistor 515, and a second pass transistor 517.

The IMC cell 500 may perform an operation between input data A input through an input terminal of the third inverter 520 and second internal data B of the SRAM cell 510 and output a NAND operation result C through an output terminal of the third inverter 520. Here, the second internal data may be output data of the second inverter 513 as described above.

Each of the first inverter 511, the second inverter 513, and the third inverter 520 may include one PMOS transistor and one NMOS transistor, and thus, the IMC cell 500 may be expressed as shown in FIG. 5B.

Referring to FIG. 5B, the first inverter 511 may include a first SRAM PMOS transistor 511-1 and a first SRAM NMOS transistor 511-2, the second inverter 513 may include a second SRAM PMOS transistor 513-1 and a second SRAM NMOS transistor 513-2, and the third inverter 520 may include a first inverter transistor 521 and a second inverter transistor 523. The first inverter transistor 521 may be an NMOS transistor, and the second inverter transistor 523 may be a PMOS transistor.

An output terminal (or a drain terminal) of the first inverter 511 may be connected to a source terminal of the first inverter transistor 521. A gate terminal of the third inverter 520 may be an input terminal of the third inverter 520, and a drain terminal of the third inverter 520 may be an output terminal of the third inverter 520.

FIG. 5C illustrates example operations of the IMC 500 in four cases that correspond to the rows of the truth table shown in FIG. 5A. In a first case 530, when A is 0 and B is 0, the first SRAM PMOS transistor 511-1 is turned on, the first SRAM NMOS transistor 511-2 is turned off, the first inverter transistor 521 is turned off, and the second inverter transistor 523 is turned on. Since the second inverter transistor 523 is turned on, C is connected to V_{DD} of the third inverter 520, and as a result, C is 1.

In a second case 540, when A is 0 and B is 1, the first SRAM PMOS transistor 511-1 is turned on, the first SRAM NMOS transistor 511-2 is turned off, the first inverter transistor 521 is turned off, and the second inverter transistor 523 is turned on. Since the second inverter transistor 523 is turned on, C is connected to V_{DD} of the third inverter 520, and as a result, C is 1.

In a third case 550, when A is 1 and B is 0, the first SRAM PMOS transistor 511-1 is turned on, the first SRAM NMOS transistor 511-2 is turned off, the first inverter transistor 521 is turned on, and the second inverter transistor 523 is turned off. Since the first inverter transistor 521 and the first SRAM PMOS transistor 511-1 are turned on, C is connected to V_{DD} of the first inverter 511, and as a result, C is 1.

In a fourth case 560, when A is 1 and B is 1, the first SRAM PMOS transistor 511-1 is turned off, the first SRAM NMOS transistor 511-2 is turned on, the first inverter transistor 521 is turned on, and the second inverter transistor 523 is turned off. Therefore, the output of the inverter 520 is connected to the ground of the first inverter 511, and as a result, C is 0.

As described in the first case 530 through the fourth case 560, the IMC cell 500 may output a NAND operation result C between the input data A and the second internal data B of the SRAM cell 510 by using eight transistors.

However, referring to FIG. 5D, since the third case 550 may correspond to a diode connection, a problem regarding a deterioration in performance of the pull-up may occur, because a case after the third case 550 is a case with an output of 0. Here, the case with an output of 0 is only the fourth case 560. Considering a case of changing from the fourth case 560 to the third case 550, A should remain 1 and B should change from 1 to 0. However, as described above, B may be a weight of the internal data in the SRAM cell 510 which is a value that does not change. Therefore, according to the third case 550, the performance of the pull-up may be deteriorated due to the diode connection, but if the weight is stored in the SRAM cell 510, the above problem can be prevented.

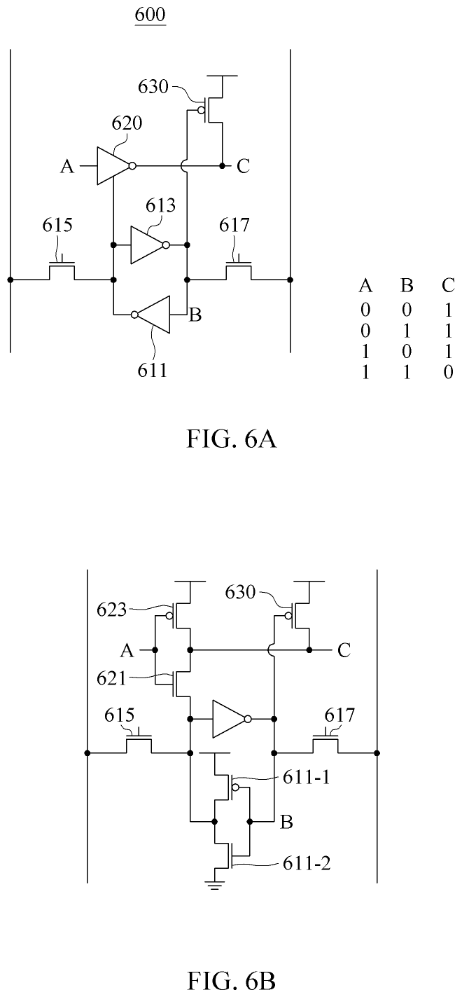

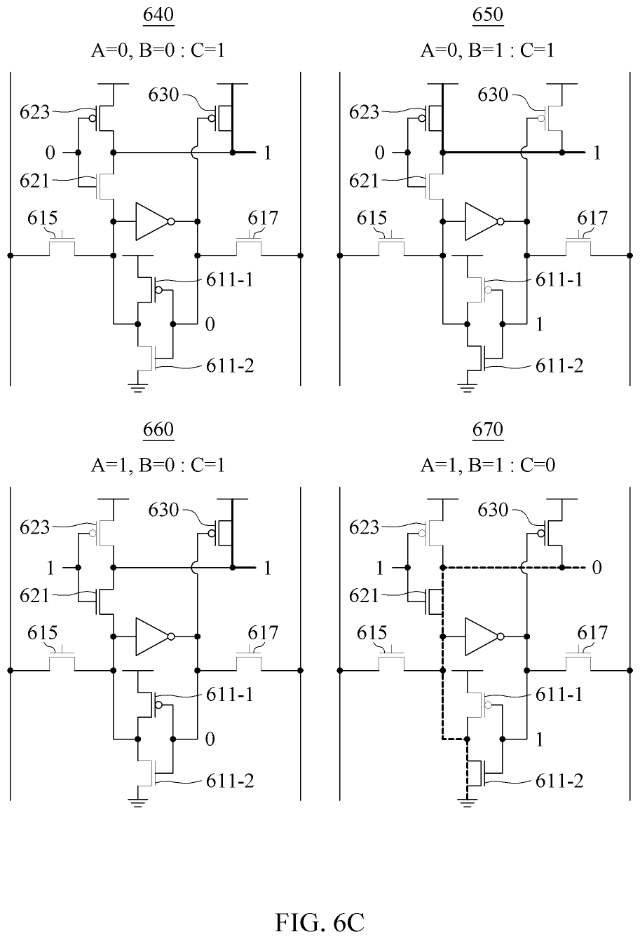

FIGS. 6A to 6C illustrate an example IMC cell for performing a NAND operation.

Referring to FIG. 6A, an IMC cell 600 may include an SRAM cell 610, a third inverter 620, and a pull-up transistor 630. The SRAM cell 610 may include a first inverter 611, a second inverter 613, a first pass transistor 615, and a second pass transistor 617.

The IMC cell 600 may perform an operation between input data A input through an input terminal of the inverter 620 and second internal data B of the SRAM cell 610 and output a NOR operation result C through an output terminal of the third inverter 620. Here, the second internal data B may be output data of the second inverter 613 as described above.

Each of the first inverter 611, the second inverter 613, and the inverter 620 may include one PMOS transistor and one NMOS transistor, and thus, the IMC cell 600 may be implemented as shown in FIG. 6B.

Referring to FIG. 6B, the first inverter 611 may include a first SRAM PMOS transistor 611-1 and a first SRAM NMOS transistor 611-2, the second inverter 613 may include a second SRAM PMOS transistor 613-1 and a second SRAM NMOS transistor 613-2, and the third inverter 620 may include a first inverter transistor 621 and a second inverter transistor 623. The first inverter transistor 621 may be an NMOS transistor, and the second inverter transistor 623 may be a PMOS transistor.

An output terminal (or a drain terminal) of the first inverter 611 may be connected to a source terminal of the second inverter transistor 623. A gate terminal of the pull-up transistor 630 may be connected to an output terminal of the second inverter 613 (or an input terminal of the first inverter 611). A gate terminal of the third inverter 620 may be an input terminal of the third inverter 620, and a drain terminal of the third inverter 620 may be an output terminal of the third inverter 620.

The IMC cell 600 may be configured to prevent occurrence of the above-described diode connection problem by using the pull-up transistor 630. FIG. 6C illustrates example operations of the IMC 600 in four cases that correspond to the rows of the truth table shown in FIG. 6A. In a first case 640, when A is 0 and B is 0, the first SRAM PMOS transistor 611-1 is turned on, the first SRAM NMOS transistor 611-2 is turned off, the first inverter transistor 621 is turned off, the second inverter transistor 623 is turned on, and the pull-up transistor 630 is turned on. Since the pull-up transistor 630 is turned on, C is connected to V_{DD} of the pull-up transistor 630, and as a result, C is 1.

In a second case 650, when A is 0 and B is 1, the first SRAM PMOS transistor 611-1 is turned on, the first SRAM NMOS transistor 611-2 is turned off, the first inverter transistor 621 is turned off, the second inverter transistor 623 is turned on, and the pull-up transistor 630 is turned off. Since the second inverter transistor 623 is turned on, C is connected to V_{DD} of the inverter 620, and as a result, C is 1.

In a third case 660, when A is 1 and B is 0, the first SRAM PMOS transistor 611-1 is turned on, the first SRAM NMOS transistor 611-2 is turned off, the first inverter transistor 621 is turned on, the second inverter transistor 623 is turned off, and the pull-up transistor 630 is turned on. Since the pull-up transistor 630 is turned on, C is connected to V_{DD} of the pull-up transistor 630, and as a result, C is 1.

In a fourth case 670, when A is 1 and B is 1, the first SRAM PMOS transistor 611-1 is turned off, the first SRAM NMOS transistor 611-2 is turned on, the first inverter transistor 621 is turned on, the second inverter transistor 623 is turned off, and the pull-up transistor 630 is turned on. Therefore, the output of the inverter 620 is connected to the ground of the first inverter 611, and as a result, C is 0.

As described in the first case 640 through the fourth case 670, the IMC cell 600 may output a NAND operation result C between the input data A and the second internal data B of the SRAM cell 610 by using nine transistors.

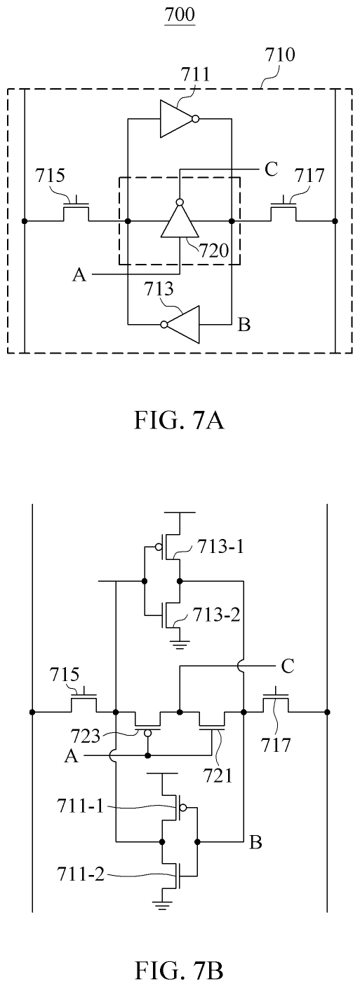

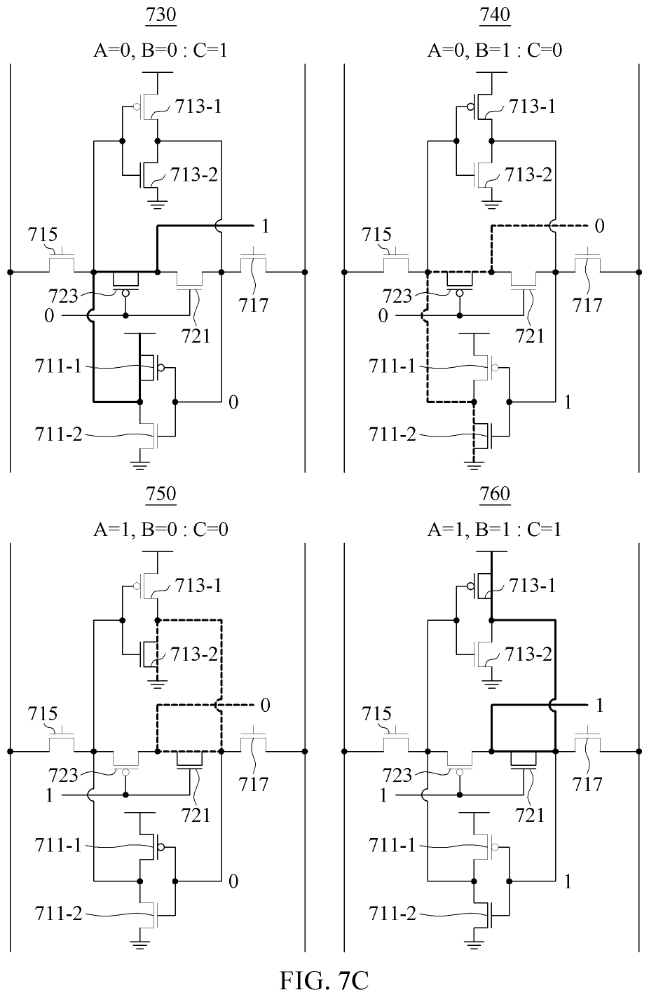

FIGS. 7A to 7C illustrate an example IMC cell for performing an XOR operation.

Referring to FIG. 7A, an IMC cell 700 may include an SRAM cell 710 and a third inverter 720. The SRAM cell 710 may include a first inverter 711, a second inverter 713, a first pass transistor 715, and a second pass transistor 717.

The IMC cell 700 may perform an operation between input data A input through an input terminal of the third inverter 720 and second internal data B of the SRAM cell 710 and output an XOR operation result C through an output terminal of the third inverter 720. Here, the second internal data B may be output data of the second inverter 713 as described above.

Each of the first inverter 711, the second inverter 713, and the third inverter 720 may include one PMOS transistor and one NMOS transistor, and thus, the IMC cell 700 may be expressed as shown in FIG. 7B.

Referring to FIG. 7B, the first inverter 711 may include a first SRAM PMOS transistor 711-1 and a first SRAM NMOS transistor 711-2, the second inverter 713 may include a second SRAM PMOS transistor 713-1 and a second SRAM NMOS transistor 713-2, and the third inverter 720 may include a first inverter transistor 721 and a second inverter transistor 723. The first inverter transistor 721 may be an NMOS transistor, and the second inverter transistor 723 may be a PMOS transistor.

An output terminal (or a drain terminal) of the first inverter 711 may be connected to a source terminal of the second inverter transistor 723, and an output terminal (or a drain terminal) of the second inverter 713 may be connected to a source terminal of the first inverter transistor 721. A gate terminal of the third inverter 720 may be an input terminal of the third inverter 720, and a drain terminal of the third inverter 720 may be an output terminal of the third inverter 720.

FIG. 7C illustrates example operations of the IMC 700 in four cases. In a first case 730, when A is 0 and B is 0, the first SRAM PMOS transistor 711-1 is turned on, the first SRAM NMOS transistor 711-2 is turned off, the second SRAM PMOS transistor 713-1 is turned off, the second SRAM NMOS transistor 713-2 is turned on, the first inverter transistor 721 is turned off, and the second inverter transistor 723 is turned on. Since the first SRAM PMOS transistor 711-1 and the second inverter transistor 723 are turned on, C is connected to V_{DD} of the inverter 720, and as a result, C is 1.

In a second case 740, when A is 0 and B is 1, the first SRAM PMOS transistor 711-1 is turned on, the first SRAM NMOS transistor 711-2 is turned off, the second SRAM PMOS transistor 713-1 is turned on, the second SRAM NMOS transistor 713-2 is turned off, the first inverter transistor 721 is turned on, and the second inverter transistor 723 is turned off. Since the first SRAM PMOS transistor 711-1 and the first inverter transistor 721 are turned on, C is connected to the ground of the inverter 720, and as a result, C is 0.

In a third case 750, when A is 1 and B is 0, the first SRAM PMOS transistor 711-1 is turned on, the first SRAM NMOS transistor 711-2 is turned off, the second SRAM PMOS transistor 713-1 is turned off, the second SRAM NMOS transistor 713-2 is turned on, the first inverter transistor 721 is turned on, and the second inverter transistor 723 is turned off. Since the first inverter transistor 721 and the second SRAM NMOS transistor 713-2 are turned on, C is connected to the ground of the second inverter 713, and as a result, C is 0.

In a fourth case 760, when A is 1 and B is 1, the first SRAM PMOS transistor 711-1 is turned off, the first SRAM NMOS transistor 711-2 is turned on, the second SRAM PMOS transistor 713-1 is turned on, the second SRAM NMOS transistor 713-2 is turned off, the first inverter transistor 721 is turned on, and the second inverter transistor 723 is turned off. Since the first inverter transistor 721 and the second SRAM PMOS transistor 713-1 are turned on, C is connected to V_{DD} of the second inverter 713, and as a result, C is 1.

As described in the first case 730 through the fourth case 760, the IMC cell 700 may output an XOR operation result C between the input data A and the second internal data B of the SRAM cell 710 by using eight transistors.

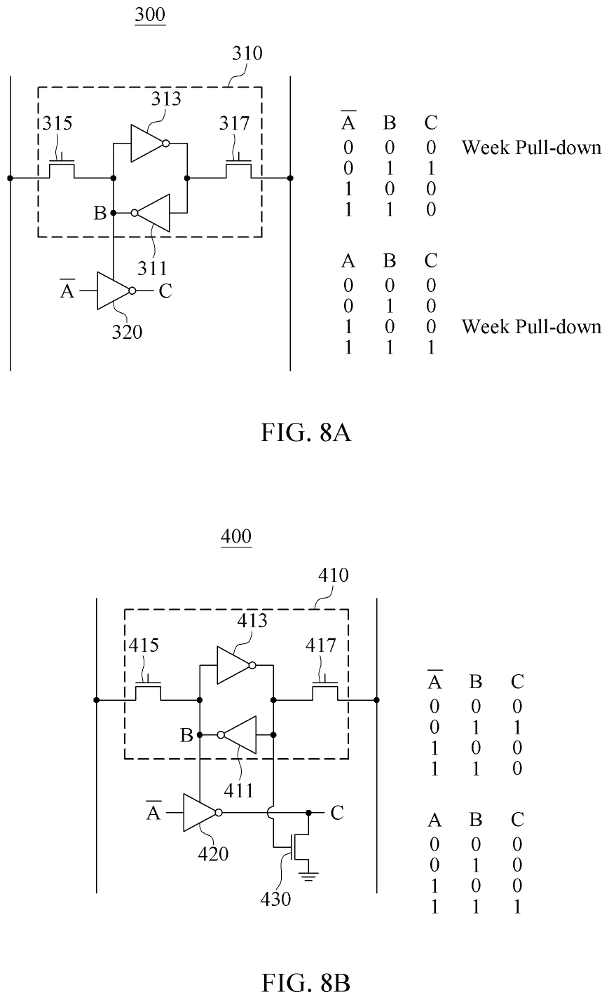

FIGS. 8A and 8B illustrate an example IMC cell for performing an AND operation according to one or more embodiments.

The description provided with reference to FIGS. 3A through 3D may apply to the example of FIG. 8A. Referring to FIG. 8A, the AND operation may be performed by using the IMC cell 300 described with reference to FIGS. 3A through 3D.

The IMC cell 300 may perform an operation between inverse input data A (inverse data of input data A) input through the input terminal of the third inverter 320 and the first internal data B of the SRAM cell 310 and output an operation result C through the output terminal of the third inverter 320. Here, the first internal data B may be output data of the first inverter 311 as described above.

The IMC cell 300 may be configured to obtain the AND operation result C between the inverse input data A and the first internal data B of the SRAM cell 310. When the operation result is adjusted to an operation result for the input data, the IMC cell 300 may obtain an AND operation result between the input data A and the first internal data B of the SRAM cell 310.

The description provided with reference to FIGS. 4A through 4C may apply to the example of FIG. 8B. Referring to FIG. 8B, the AND operation may be performed by using the IMC cell 400 described with reference to FIGS. 4A through 4C.

The IMC cell 400 may be configured to perform an operation between inverse input data A (inverse data of input data A) input through the input terminal of the third inverter 420 and the first internal data B of the SRAM cell 410, and output an operation result (e.g., C) through the output terminal of the third inverter 420. Here, the first internal data may be output data of the first inverter 411 as described above.

The IMC cell 400 may be configured to obtain the AND operation result C between the inverse input data A and the first internal data B of the SRAM cell 410. When the operation result is adjusted to an operation result for the input data, the IMC cell 400 may obtain an AND operation result between the input data A and the first internal data B of the SRAM cell 410.

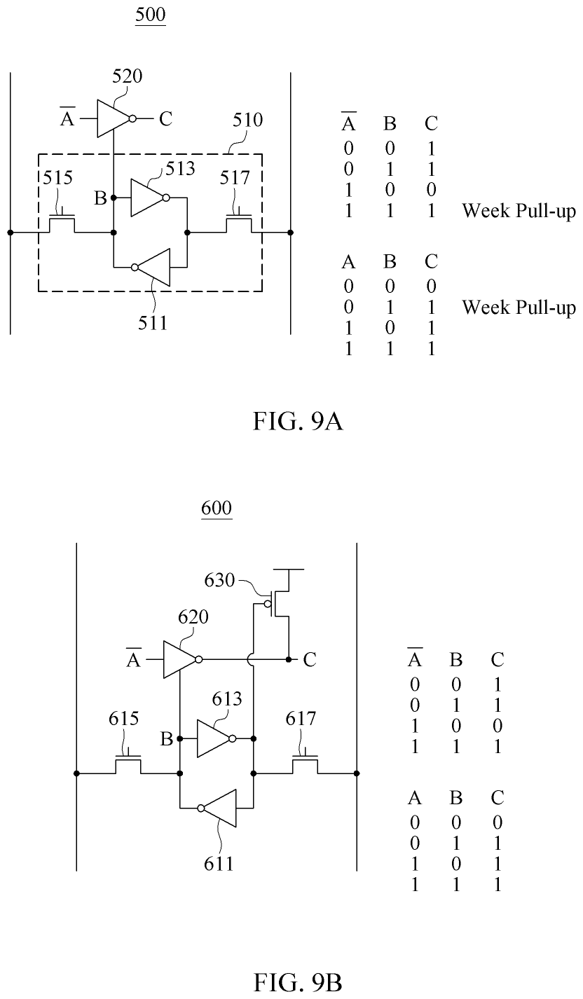

FIGS. 9A and 9B illustrate an example IMC cell for performing an OR operation.

The description provided with reference to FIGS. 5A through 5D may apply to the example of FIG. 9A. Referring to FIG. 9A, the OR operation may be performed by using the IMC cell 500 described with reference to FIGS. 5A through 5D.

The IMC cell 500 may be configured to perform an operation between inverse input data A (inverse data of input data A) input through the input terminal of the third inverter 520 and the first internal data B of the SRAM cell 510 and output an OR operation result C through the output terminal of the third inverter 520. Here, the first internal data B may be output data of the first inverter 511 as described above.

The IMC cell 500 may be configured to obtain the operation result C between the inverse input data Ā and the first internal data B of the SRAM cell 510. When the operation result is adjusted to an operation result for the input data, the IMC cell 500 may obtain an OR operation result between the input data A and the first internal data B of the SRAM cell 510.

The description provided with reference to FIGS. 6A through 6C may apply to the example of FIG. 9B. Referring to FIG. 9B, the AND operation may be performed by using the IMC cell 600 described with reference to FIGS. 6A through 6C.

The IMC cell 600 may be configured to perform an operation between inverse input data Ā (inverse data of input data A) input through the input terminal of the third inverter 620 and the first internal data B of the SRAM cell 610 and output an AND operation result C through the output terminal of the third inverter 620. Here, the first internal data B may be output data of the first inverter 611 as described above.

The IMC cell 600 may be configured to obtain the operation result C between the inverse input data Ā and the first internal data B of the SRAM cell 610. When the operation result is adjusted to an operation result for the input data, the IMC cell 600 may obtain an AND operation result between the input data A and the first internal data B of the SRAM cell 610

The memory device 110, the operation layer 190, the filters 210, the IFMs 230, and the OFMs 250 described herein and disclosed herein described with respect to FIGS. 1-9B are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9B that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROM, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An apparatus, comprising:
a static random access memory (SRAM) cell comprising a first inverter and a second inverter; and
a third inverter comprising a first inverter transistor and a second inverter transistor,
wherein an output terminal of the first inverter is connected to a source terminal of the second inverter transistor.

2. The apparatus of claim 1, wherein the apparatus is configured to perform an operation between input data input through an input terminal of the third inverter and output data of the second inverter and output a result of the operation through an output terminal of the third inverter.

3. The apparatus of claim 2, wherein the result of the operation comprises a NOR operation result between the input data and the output data of the second inverter.

4. The apparatus of claim 1, further comprising:
a pull-down transistor,
wherein a gate terminal of the pull-down transistor is connected to an output terminal of the second inverter.

5. The apparatus of claim 4,
wherein the pull-down transistor is an NMOS transistor, and
wherein an output terminal of the third inverter is connected to a drain terminal of the pull-down transistor.

6. The apparatus of claim 1, wherein apparatus is configured to perform an operation between inverse input data input through an input terminal of the third inverter and output data of the first inverter and output a result of the operation through an output terminal of the third inverter.

7. The apparatus of claim 6, wherein the result of the operation comprises an AND operation result between input data corresponding to the inverse input data and the output data of the first inverter.

8. An apparatus comprising:
a static random access memory (SRAM) cell comprising a first inverter and a second inverter; and
a third inverter comprising a first inverter transistor and a second inverter transistor,
wherein an output terminal of the first inverter is connected to a source terminal of the first inverter transistor.

9. The apparatus of claim 8,
wherein the apparatus is configured to perform an operation between input data input through an input terminal of the third inverter and output data of the first inverter and output a result of the operation through an output terminal of the third inverter.

10. The apparatus of claim 9,
wherein the result of the operation comprises a NAND operation result between the input data and the output data of the first inverter.

11. The apparatus of claim 8, further comprising:
a pull-up transistor,
wherein a gate terminal of the pull-down transistor is connected to an output terminal of the first inverter.

12. The apparatus of claim 11,
wherein the pull-up transistor is a PMOS transistor, and
wherein an output terminal of the third inverter is connected to a drain terminal of the pull-up transistor.

13. The apparatus of claim 8, wherein the apparatus is configured to perform an operation between inverse input data input through an input terminal of the third inverter and output data of the first inverter and output a result of the operation through an output terminal of the third inverter.

14. The apparatus of claim 13, wherein the result of the operation comprises an OR operation result between input data corresponding to the inverse input data and the output data of the first inverter.

15. An apparatus comprising:
a static random access memory (SRAM) cell comprising a first inverter and a second inverter; and
a third inverter comprising a first inverter transistor and a second inverter transistor,
wherein an output terminal of the second inverter is connected to a source terminal of the first inverter transistor, and an output terminal of the first inverter is connected to a source terminal of the second inverter transistor.

16. The apparatus of claim 15, wherein the apparatus is configured to perform an operation between input data input through an input terminal of the third inverter and output data of the second inverter and output a result of the operation through an output terminal of the third inverter.

17. The apparatus of claim 16, wherein the result of the operation comprises an XOR operation result between the input data and the output data of the second inverter.

18. A method, comprising:
performing a first operation between input data input through an input terminal of a third inverter and output data of a second inverter and output a result of the operation through an output terminal of the third inverter; and
perform a second operation between inverse input data input through an input terminal of the third inverter and output data of a first inverter and output a result of the operation through an output terminal of the third inverter.

19. The method of claim 18, wherein the result of the first operation comprises an NOR operation result between the input data and the output data of the second inverter.

20. The method of claim 18, wherein the result of the second operation comprises an AND operation result between input data corresponding to the inverse input data and the output data of the first inverter.
